(19) United States
(12) Patent Application Publication
(10) Pub. No.: US 2014/0198509 A1
(43) Pub. Date: Jul. 17, 2014

(54) SEMICONDUCTOR LASER POSITIONING MEMBER AND OPTICAL UNIT

(71) Applicant: Sony Corporation, Tokyo (JP)

(72) Inventors: Mikio Takiguchi, Kanagawa (JP); Tomoki Ono, Kanagawa (JP)

(73) Assignee: Sony Corporation, Tokyo (JP)

(21) Appl. No.: 14/154,950

(22) Filed: Jan. 14, 2014

(30) Foreign Application Priority Data
Jan. 17, 2013 (JP) 2013-006521

(51) Int. Cl. H01S 5/022

(52) U.S. Cl. CPC H01S 5/02236
USPC 362/382

(57) ABSTRACT

A semiconductor laser positioning member includes: a base section having a through hole into which a semiconductor laser is to be inserted, the semiconductor laser being configured to be disposed in a terminal insertion hole and having a pair of engagement recesses, the terminal insertion hole being formed in a holder; and a pair of plate spring sections projecting from an opening edge of the through hole, the plate spring sections being opposed to each other. The plate spring sections are each formed in a symmetrical shape in a circumferential direction of the through hole, the base section is overlapped with the holder when the semiconductor laser is inserted into the through hole, and the plate spring sections are engaged with the respective engagement recesses, and are each elastically deformable in an optical axis direction of the semiconductor laser when the semiconductor laser is inserted into the through hole.

### CROSS REFERENCE TO RELATED APPLICATIONS

This application claims the benefit of Japanese Priority Patent Application JP 2013-006521 filed Jan. 17, 2013, the entire contents of which are incorporated herein by reference.

### BACKGROUND

The present technology relates to a technical field of a positioning member and an optical unit. Specifically, the present technology relates to a technical field of improving positioning accuracy of a semiconductor laser with respect to a holder by providing a plate spring section that is engaged with an engagement recess of the semiconductor laser.

A semiconductor laser is widely used for, for example, a light source of a printer such as a laser printer, a light source of a measuring device such as a laser range finder, and a light source of a display unit such as a projector.

The semiconductor laser includes a laser emission section, a flange, and a terminal section. The laser emission section is configured to emit light, the flange has a diameter larger than that of the laser emission section, and the terminal section is connected to a drive circuit. Such a semiconductor laser is configured as a part of an optical unit, and the optical unit may include, for example, the semiconductor laser, a holder holding the semiconductor laser, and a fixing member fixing the semiconductor laser to the holder. The holder has an insertion hole into which the semiconductor laser is to be inserted. The semiconductor laser is partially inserted into the insertion hole to be held by the holder, and is pressed by the fixing member to be fixed to the holder.

In the above-described optical unit, to improve uniformity, a polarization ratio, and the like of a light source, accuracy in positioning the semiconductor laser with respect to the holder is important. Therefore, the flange of the semiconductor laser is provided with a pair of engagement recesses for positioning.

One of methods of positioning such an optical unit having the semiconductor laser is a method of bringing positioning pins provided on the holder into contact with the engagement recesses.

However, by the above-described positioning method, when an outer diameter of the flange becomes small due to an outer diameter tolerance of the semiconductor laser, a gap occurs between the engagement recess and the positioning pin, which lowers the positioning accuracy. In addition, the positioning accuracy of the semiconductor laser is lowered by machining accuracy of the positioning pins, and the like.

In addition, other than the above-described method, there is a method in which an insertion hole having the same shape as the outer shape of the flange of the semiconductor laser is formed in the holder, and the flange is engaged with the insertion hole to perform positioning.

Also by the method, however, the positioning accuracy of the semiconductor laser is lowered by the outer diameter tolerance of the semiconductor laser and the insertion hole.

Therefore, as another positioning method, there is proposed a method in which positioning projections to be coupled with engagement recesses are provided, a circular inclined surface is formed in a part of a holder to be in contact with a flange (annular flange-like base) of a semiconductor laser (a laser diode), and the positioning projections are inserted into a pair of engagement recesses as well as the inclined surface is pressed against an edge of the flange from a terminal side to perform positioning of the semiconductor laser (for example, Japanese Unexamined Patent Application Publication No. 2005-190572).

### SUMMARY

By the above-described method described in Japanese Unexamined Patent Application Publication No. 2005-190572, it is possible to suppress displacement in a straight line direction on a plane perpendicular to an optical axis. However, in the case where a gap occurs between the engagement recess of the flange and the positioning projection due to an outer diameter tolerance of the semiconductor laser or an optical base, displacement in a rotation direction around the optical axis may occur.

It is desirable to provide a semiconductor laser positioning member and an optical unit that are capable of improving positioning accuracy of a semiconductor laser with respect to a holder.

According to an embodiment of the technology, there is provided a semiconductor laser positioning member including: a base section having a through hole into which a semiconductor laser is to be inserted, the semiconductor laser being configured to be disposed in a terminal insertion hole and having a pair of engagement recesses, the terminal insertion hole being formed in a holder; and a pair of plate spring sections projecting from an opening edge of the through hole toward a mutually approaching direction, the pair of plate spring sections being opposed to each other by substantially 180 degrees with a center of the through hole in between. The plate spring sections are each formed in a symmetrical shape in a circumferential direction of the through hole, the base section is overlapped with the holder when the semiconductor laser is inserted into the through hole, and the plate spring sections are engaged with the respective engagement recesses, and are each elastically deformable in an optical axis direction of the semiconductor laser when the semiconductor laser is inserted into the through hole.

Therefore, according to the semiconductor laser positioning member of the embodiment of the technology, positioning of the semiconductor laser with respect to the holder is performed both in a straight line direction on a plane perpendicular to the optical axis and in a rotation direction around the optical axis.

Advantageously, in the semiconductor laser positioning member described above, each of the engagement recesses may have two engagement surfaces, and the plate spring section may be desirably engaged with the two engagement surfaces at positions separated from each other in a direction substantially perpendicular to the optical axis direction.

When each of the engagement recesses has the two engagement surfaces, and the plate spring section is engaged with the two engagement surfaces at the positions separated from each other in the direction perpendicular to the optical axis direction, the positioning of the semiconductor laser with respect to the holder is performed with higher accuracy both in the straight line direction on the plane perpendicular to the optical axis and in the rotation direction around the optical axis.

Advantageously, in the semiconductor laser positioning member described above, each of the plate spring sections may have corners, and the corners may be in contact with the corresponding engagement surfaces.

When each of the plate spring sections has the corners, and the corners are respectively in contact with the engagement surfaces, parts other than the corners are hardly deformed, and elastic deformation of the corners caused by engagement with the engagement recess hardly affects the parts other than the corners.

Advantageously, in the semiconductor laser positioning member described above, a part or all of a peripheral surface of each of the plate spring sections may have a curved surface, and the curved surface may be desirably in contact with the engagement surfaces.

When a part or all of the peripheral surface of each of the plate spring sections is formed as the curved surface, and the curved surface is in contact with the engagement surfaces, curved surface parts are in contact with the engagement surfaces.

Advantageously, in the semiconductor laser positioning member described above, a part where an outer periphery of the plate spring section and the opening edge of the through hole are continued may have a curved surface.

When the part where the outer periphery of the plate spring section and the opening edge of the through hole are continued is formed as the curved surface, stress concentration hardly occurs in a part of the plate spring section connected to the base section at the time of engagement between the plate spring section and the engagement recess.

Advantageously, in the semiconductor laser positioning member described above, the plate spring section may include a base end and a wide part, and the base end may be connected to the base section and may have a width that is smaller than a width of the wide part being the largest in width.

When the plate spring section is formed to allow the width of the base end that is connected to the base section, to be smaller than that of the wide part that is the largest in width, the plate spring section is easily elastically deformed.

Advantageously, in the semiconductor laser positioning member described above, the plate spring section may include a base end, and the base end may be connected to the base section and is the largest in width.

When the plate spring section is formed to allow the base end that is connected to the base section, to be the largest in width, the strength of the base end is enhanced.

Advantageously, in the semiconductor laser positioning member described above, each of the plate spring sections may be configured of two projections, and the projections may be desirably respectively engaged with the two engagement surfaces.

When the plate spring section is configured of the two projections, and the projections are respectively engaged with the two engagement surfaces, influence of the elastic deformation of one of the projections on the other projection is suppressed.

Advantageously, in the semiconductor laser positioning member described above, the plate spring section may have in a rectangular shape.

When the plate spring section is formed in a rectangular shape, the plate spring section is allowed to be formed in a simple shape.

According to an embodiment of the technology, there is provided an optical unit including: a holder having a terminal insertion hole into which a semiconductor laser is configured to be arranged, the semiconductor laser having a pair of engagement recesses; a positioning member having a base section and a pair of plate spring sections, the base section having a through hole into which the semiconductor laser is configured to be inserted, the pair of plate spring sections projecting from an opening edge of the through hole toward a mutually approaching direction, and being opposed to each other by substantially 180 degrees with a center of the through hole in between; and a fixing member fixing the positioning member and the semiconductor laser to the holder. The plate spring sections is each formed in a symmetrical shape in a circumferential direction of the through hole, the base section is overlapped with the holder when the semiconductor laser is inserted into the through hole, and the plate spring sections are engaged with the respective engagement recesses, and are each elastically deformable in an optical axis direction of the semiconductor laser when the semiconductor laser is inserted into the through hole.

Therefore, according to the optical unit of the embodiment of the technology, the semiconductor laser is fixed to the holder in a state where the positioning of the semiconductor laser with respect to the holder is performed both in the straight line direction on the plane perpendicular to the optical axis and in the rotation direction around the optical axis.

The semiconductor laser positioning member according to the embodiment of the technology includes: a base section having a through hole into which a semiconductor laser is configured to be inserted, the semiconductor laser being disposed in a terminal insertion hole and having a pair of engagement recesses, the terminal insertion hole being formed in a holder; and a pair of plate spring sections projecting from an opening edge of the through hole toward a mutually approaching direction, the pair of plate spring sections being opposed to each other by substantially 180 degrees with a center of the through hole in between. The plate spring sections are each formed in a symmetrical shape in a circumferential direction of the through hole, the base section is overlapped with the holder when the semiconductor laser is inserted into the through hole, and the plate spring sections are engaged with the respective engagement recesses, and are each elastically deformable in an optical axis direction of the semiconductor laser when the semiconductor laser is inserted into the through hole.

Therefore, displacement in the straight line direction on the plane perpendicular to the optical axis and displacement in the rotation direction around the optical axis are suppressed, thereby making it possible to improve positioning accuracy of the semiconductor laser with respect to the holder.

According to one embodiment of the present technology, advantageously, each of the engagement recesses may have the two engagement surfaces, and the plate spring section may be engaged with the two engagement surfaces at the positions separated from each other in the direction substantially perpendicular to the optical axis direction.

Therefore, displacement of the semiconductor laser with respect to the holder is suppressed both in the straight line direction on the plane perpendicular to the optical axis and in the rotation direction around the optical axis, thereby making it possible to further improve the positioning accuracy of the semiconductor laser with respect to the holder.

According to one embodiment of the present technology, advantageously, each of the plate spring sections may have the corners, and the corners may be in contact with the corresponding engagement surfaces.

Therefore, when the corners of the plate spring section are respectively in contact with the engagement surfaces, the parts other than the corners are hardly deformed, and elastic deformation caused by the engagement hardly affects the parts other than the corners. Accordingly, it is possible to improve the positioning accuracy of the semiconductor laser with respect to the holder.

According to one embodiment of the present technology, advantageously, a part or all of the peripheral surface of each of the plate spring sections may have the curved surface, and the curved surface may be in contact with the engagement surfaces.

Therefore, when the curved surface is in contact with the engagement surfaces, the plate spring section is hardly damaged, and abrasion of the plate spring section is also allowed to be suppressed.

According to one embodiment of the present technology, advantageously, the part where the outer periphery of the plate spring section and the opening edge of the through hole are continued may have a curved surface.

Therefore, when the part where the outer periphery of the plate spring section and the opening edge of the through hole are continued is formed as the curved surface, stress concentration hardly occurs in a part of the plate spring section connected to the base section at the time of engagement between the plate spring section and the engagement recess. Accordingly, it is possible to suppress damage of the plate spring section.

According to one embodiment of the present technology, advantageously, the plate spring section may include a base end and a wide part, and the base end maybe connected to the base section and may have a width that is smaller than a width of the wide part being the largest in width.

Therefore, since the width of the base end of the plate spring section is small, the plate spring section is easily elastically deformed, and it is possible to suppress load to the semiconductor laser while securing high positioning accuracy of the semiconductor laser.

According to one embodiment of the present technology, advantageously, the plate spring section may include a base end, and the base end may be connected to the base section and may be the largest in width.

Therefore, since the base end of the plate spring section is formed to be the largest in width, strength of the base end is enhanced, thereby making it possible to suppress damage and unnecessary deformation of the plate spring section.

According to one embodiment of the present technology, advantageously, each of the plate spring sections may be configured of the two projections, and the projections may be engaged with the respective two engagement surfaces.

Therefore, when the two projections of the plate spring section are engaged with the two engagement surfaces, influence of the elastic deformation of one of the projections on the other projection is suppressed. Accordingly, it is possible to easily apply uniform force to the two engagement surfaces, and to improve the positioning accuracy of the semiconductor laser with respect to the holder.

According to one embodiment of the present technology, advantageously, the plate spring section may have a rectangular shape.

Therefore, the plate spring section is easily formed, which makes it possible to improve working efficiency and to perform cost reduction in forming operation.

The optical unit according to the embodiment of the technology includes: a holder having a terminal insertion hole into which a semiconductor laser is configured to be arranged, the semiconductor laser having a pair of engagement recesses; a positioning member having a base section and a pair of plate spring sections, the base section having a through hole into which the semiconductor laser is configured to be inserted, the pair of plate spring sections projecting from an opening edge of the through hole toward a mutually approaching direction, and being opposed to each other by substantially 180 degrees with a center of the through hole in between; and a fixing member fixing the positioning member and the semiconductor laser to the holder. The plate spring sections are each formed in a symmetrical shape in a circumferential direction of the through hole, the base section is overlapped with the holder when the semiconductor laser is inserted into the through hole, and the plate spring sections are engaged with the respective engagement recesses, and are each elastically deformable in an optical axis direction of the semiconductor laser when the semiconductor laser is inserted into the through hole.

Therefore, since the semiconductor laser is fixed to the holder in a state where displacement in the straight line direction on the plane perpendicular to the optical axis and displacement in the rotation direction around the optical axis are suppressed, it is possible to improve the positioning accuracy of the semiconductor laser with respect to the holder.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a diagram illustrating, together with FIG. 2 to FIG. 18, a semiconductor laser positioning member and an optical unit according to some embodiments of the present technology, and is a perspective view of the optical unit.

FIG. 2 is an exploded perspective view of the optical unit.

FIG. 3 is an enlarged plan view illustrating a part of the positioning member.

FIG. 4 is an enlarged plan view illustrating a relationship between plate spring sections of the positioning member and engagement recesses of a semiconductor laser.

FIG. 5 is a diagram illustrating, together with FIG. 6 to FIG. 10, a state where the semiconductor laser is positioned with respect to a holder by the positioning member, and is an enlarged sectional view illustrating a state where the semiconductor laser is disposed on the holder.

FIG. 6 is an enlarged sectional view illustrating a state where a light emission section of the semiconductor laser is inserted into a positioning hole of the positioning member.

FIG. 7 is an enlarged sectional view illustrating a state where a bottom surface of the positioning member is in contact with a top surface of a flange of the semiconductor laser.

FIG. 8 is an enlarged sectional view illustrating a state where the plate spring sections of the positioning member are engaged with the engagement recesses of the semiconductor laser, and the plate spring sections are elastically deformed.

FIG. 9 is an enlarged sectional view illustrating a state where the bottom surface of the positioning member is in contact with a top surface of the holder, and the positioning of the semiconductor laser is completed.

FIG. 10 is an enlarged sectional view illustrating a state where the semiconductor laser is positioned and fixed to the holder by a fixing member.

FIG. 11 is an enlarged plan view illustrating a plate spring section according to a first modification.

FIG. 12 is an enlarged plan view illustrating a plate spring section according to a second modification.

FIG. 13 is an enlarged plan view illustrating a plate spring section according to a third modification.

FIG. 14 is an enlarged plan view illustrating a plate spring section according to a fourth modification.

FIG. 15 is an enlarged plan view illustrating another example of the plate spring section.

FIG. 16 is an enlarged plan view illustrating still another example of the plate spring section.

FIG. 17 is a plan view illustrating an example in which semiconductor lasers are arranged in two lines.

FIG. 18 is a plan view illustrating an example in which semiconductor lasers are arranged while being rotated by 90 degrees.

### DETAILED DESCRIPTION

Hereinafter, embodiments of a semiconductor laser positioning member and an optical unit of the present technology will be described in detail with reference to drawings.

Incidentally, in the following description, a light emission direction of a semiconductor laser is referred to as a top direction. However, directions described hereinafter are used merely for convenience of description, and the directions are not limited thereto in embodiments of the present technology.

### (Configuration of Optical Unit)

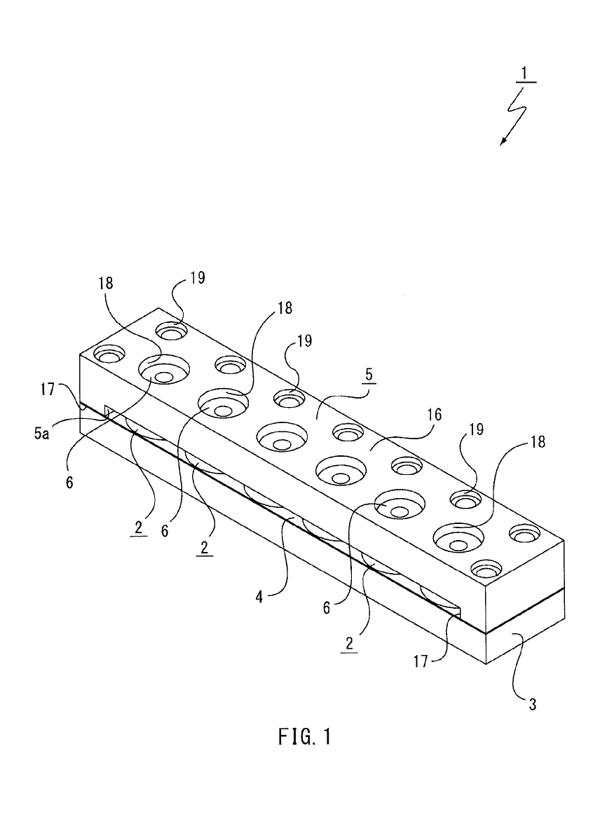

First, a configuration of an optical unit 1 is described (see FIG. 1 to FIG. 4).

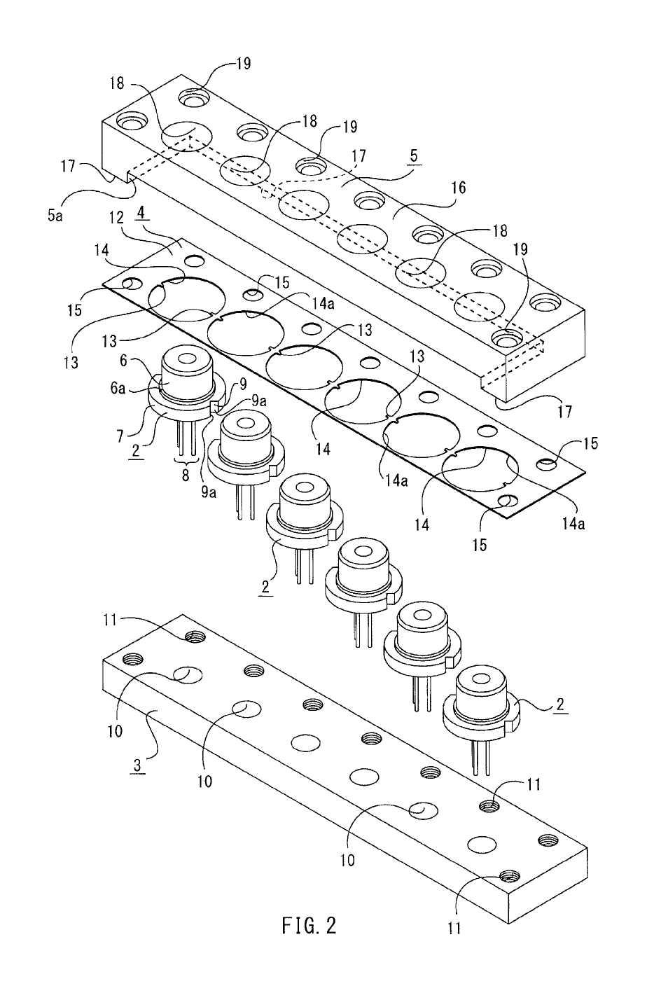

The optical unit 1 includes semiconductor lasers 2 each configured to emit laser light, a holder 3 holding the semiconductor laser 2, a positioning member 4 positioning the semiconductor laser 2 with respect to the holder 3, and a fixing member 5 fixing the semiconductor lasers 2 to the holder 3 (see FIG. 1 and FIG. 2).

Each of the semiconductor lasers 2 includes a light emission section 6 configured to emit light, a flange 7 having a diameter larger than that of the light emission section 6, and a terminal section 8 including three terminals that are connected to a drive circuit (not shown). A part where the light emission section 6 is joined to the flange 7 is a joint part 6a that has a diameter larger than the diameter of the light emission section 6 and smaller than the diameter of the flange 7. The flange 7 includes a pair of engagement recesses 9 that are opposed to each other by 180 degrees with an optical axis in between, and each of the engagement recesses 9 has two engagement surfaces 9a.

The two engagement surfaces 9a intersect with each other at a substantially right angle, and each of the engagement surfaces 9a faces in a direction perpendicular to a vertical direction.

For example, the holder 3 may be formed in an oblong plate shape. Incidentally, in the following description, the longitudinal direction of the holder 3 is referred to as a lateral direction.

In the holder 3, circular terminal insertion holes 10 are formed separately from one another in the longitudinal direction. The terminal sections 8 of the semiconductor laser 2 are inserted into the respective terminal insertion holes 10. The size of each of the terminal insertion holes is smaller than that of the flange 7 of the semiconductor laser 2. In the holder 3, screw holes 11 are formed separately from one another.

The positioning member 4 is configured of a base section 12 and plate spring sections 13, and for example, may be formed of a thin sheet metal material in a rectangular shape such as an oblong shape.

It is to be noted that the positioning member 4 may be formed of an inorganic fiber such as a carbon fiber and a glass fiber, or resin such as an acrylic resin, or the like, besides a metal material such as stainless steel.

The positioning member 4 has the vertical and lateral sizes same as those of the holder 3. In the base section 12, through holes 14 are formed separately from one another in the longitudinal direction. The flanges 7 of the semiconductor laser 2 are inserted into the respective through holes 14. The diameter of each of the through holes 14 is slightly larger than the diameter of the flange 7 of the semiconductor laser 2. In the base section 12, screw insertion holes 15 are formed separately from one another.

The plate spring sections 13 are provided so that the plate spring sections 13 in each pair are opposed to each other by 180 degrees with the center of the through hole 14 in between.

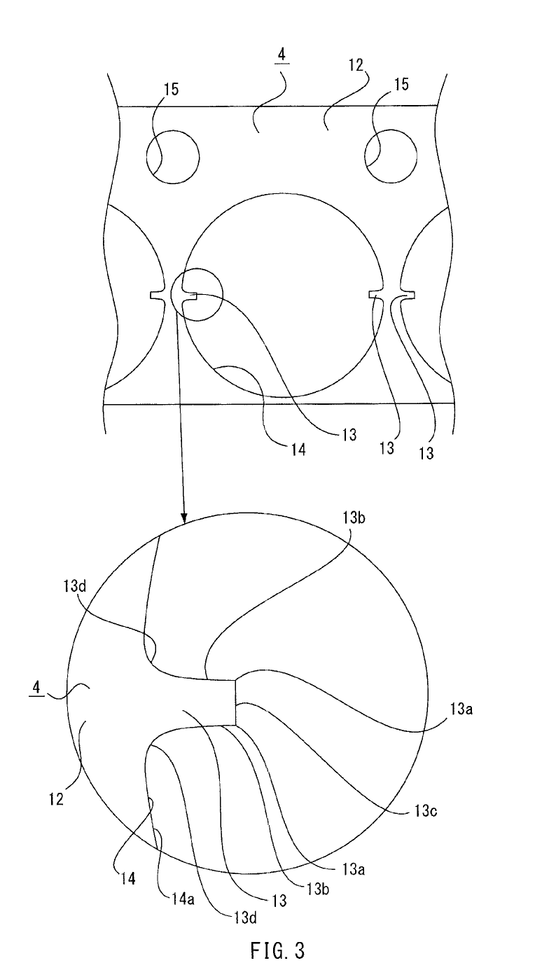

The pair of plate spring sections 13 projects toward a mutually approaching direction from an opening edge 14a of the through hole 14 (see FIG. 2 and FIG. 3). Each of the plate spring sections 13 is formed in a substantially oblong shape. Parts on both sides in a width direction of a front end part of the plate spring section 13 are provided as corners 13a. Since the shape of the plate spring section 13 is simple, the plate spring section 13 is easily formed.

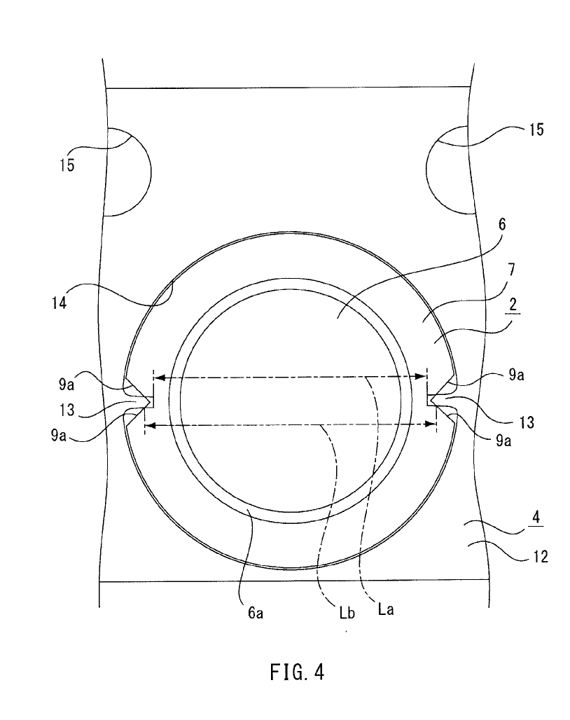

As will be described later, the pair of plate spring sections 13 is engaged with the two engagement recesses 9 that are provided in the flange 7 of the semiconductor laser 2. At this time, to ensure engagement between the corners 13a of the respective plate spring sections 13 and the engagement surfaces 9a of the respective engagement recesses 9, a distance La between the front end parts of the plate spring sections 13 is set to be smaller than a distance Lb between a point where the corner 13a of one of the plate spring sections 13 is in contact with the engagement surface 9a and a point where the corner 13a of the other plate spring section 13 is in contact with the engagement surface 9a (see FIG. 4). Further, when an outer diameter tolerance of the semiconductor laser 2 is represented by AC there is a possibility that the position of the engagement recess 9 shifts inward by up to Δφ/2 from a position of the engagement recess 9 in design. Therefore, the plate spring section 13 has a length so as to be in contact with the engagement recess 9 even in the case where the position of the engagement recess 9 is shifted inward by Δφ/2. In other words, the distance La is set to be smaller than Lb−φ (La≦Lb−φ).

The outer periphery of the plate spring section 13 is formed of side edges 13b on both sides, a front edge 13c, and curved continuous surfaces 13d each where the side edge 13b is connected to the opening edge 14a of the through hole 14 (see FIG. 3).

The fixing member 5 has the vertical and lateral sizes same as those of the holder 3 (see FIG. 1 and FIG. 2). The fixing member 5 has a laser arrangement section 16 formed in an oblong shape and three side walls 17. The side walls 17 project downward from right and left end parts and rear end part of peripheral parts of the laser arrangement section 16. Therefore, an arrangement recess 5a opened downward and forward is formed in the fixing member 5.

Laser fixing holes 18 are formed separately from one another in the longitudinal direction in the laser arrangement section 16. Screw insertion holes 19 are formed separately from one another in the laser arrangement section 16.

(Positioning of Semiconductor Laser with Respect to Holder)

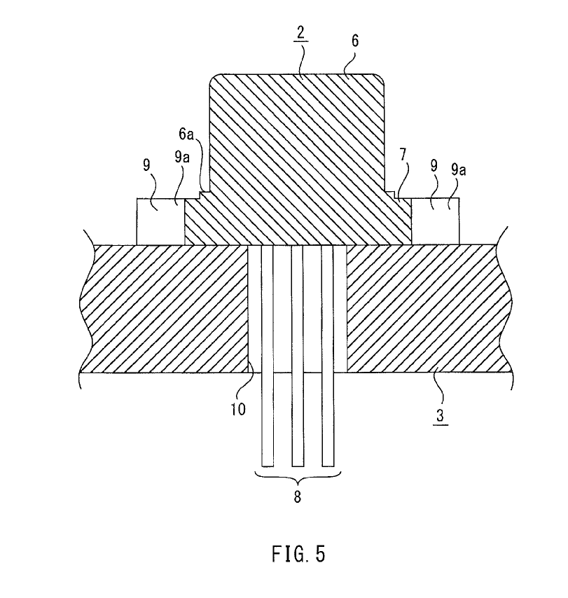

Positioning procedure of the semiconductor lasers 2 with respect to the holder 3 is described below (see FIG. 5 to FIG. 10).

Incidentally, in the optical unit 1, although the plurality of semiconductor lasers 2 are attached and positioned to the holder 3 at a time, the procedure is described below assuming that one semiconductor laser 2 is positioned to the holder 3 for simplification of the description.

First, the terminal section 8 of the semiconductor laser 2 is inserted into the terminal arrangement hole 10 of the holder 3 from above so that the engagement recesses 9 of the flange 7 are located on the right and the left, to dispose the semiconductor laser 2 on the holder 3 (see FIG. 5). In the state where the semiconductor laser 2 is disposed on the holder 3, the flange 7 is mounted on the top surface of the holder 3.

Next, the positioning member 4 is attached to the holder 3 from above. At the time of attaching the positioning member 4 to the holder 3, the positioning member 4 is moved downward to approach the holder 3 as described below.

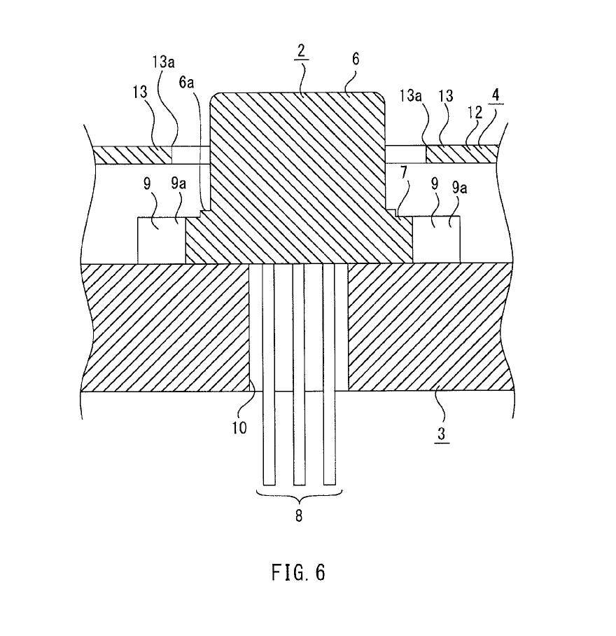

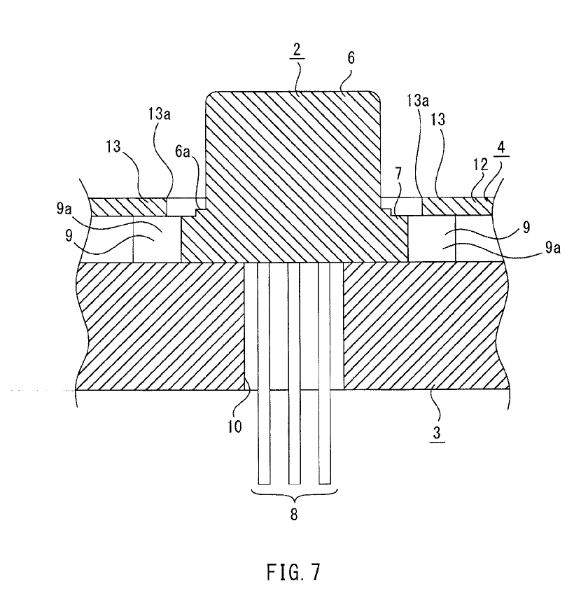

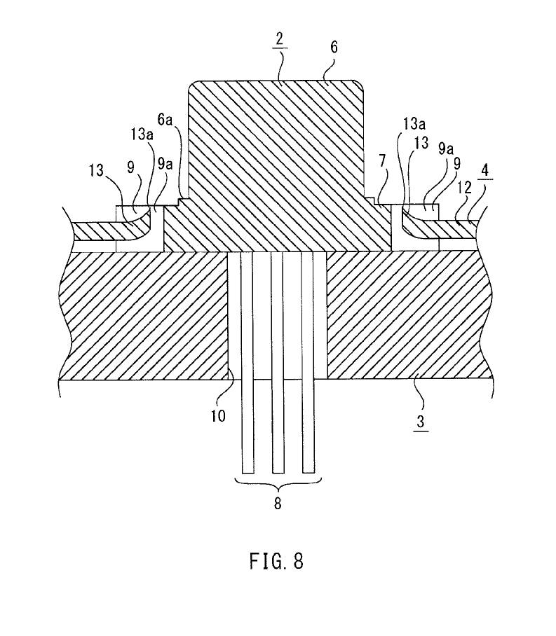

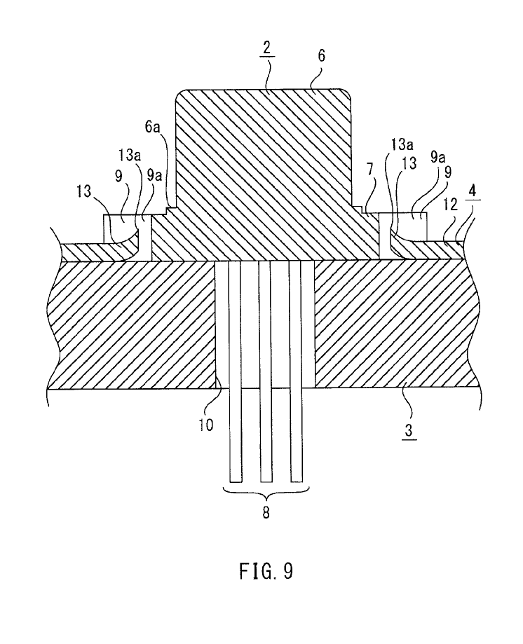

As the positioning member 4 approaches the holder 3, first, the light emission section 6 is inserted into the through hole 14 (see FIG. 6). As the positioning member 4 further approaches the holder 3, the bottom surfaces of the respective plate spring sections 13 are in contact with the top surface of the flange 7 (see FIG. 7). As the positioning member 4 further approaches the holder 3 from the above-described contact state, the corners 13a of the respective plate spring sections 13 are in contact with the engagement surfaces 9a, and thus the plate spring sections 13 are bent. The plate spring sections 13 are elastically deformed in a state of being gradually displaced upward toward the front end thereof (see FIG. 8). As the positioning member 4 further approaches the holder 3, the bottom surface of the base section 12 is in contact with the top surface of the holder 3 (see FIG. 9).

In the state where the bottom surface of the base section 12 is in contact with the top surface of the holder 3, the four corners 13a of the plate spring sections 13 in the elastically deformed state are engaged with the engagement surfaces 9a, respectively, and the semiconductor laser 2 are thus pressed by the plate spring sections 13. As a result, the positioning of the semiconductor laser 2 with respect to the holder 3 in the front-back direction and the lateral direction is performed. Further, since the plate spring sections 13 are symmetrically formed in a circumferential direction of the through hole 14, the positioning is also performed in a rotation direction around the optical axis.

As described above, the corners 13a of the plate spring sections 13 are engaged with the engagement surfaces 9a of the semiconductor laser 2, and therefore, parts other than the corners 13a are hardly deformed and elastic deformation caused by engagement hardly affects the parts other than the corners 13a.

In addition, since parts where the side edges 13b of the plate spring section 13 are respectively connected to the opening edges 14a of the through hole 14 are formed as the curved continuous surfaces 13d, stress concentration hardly occurs in a part of the plate spring section 13 connected with the base section 12 when the plate spring section 13 is engaged with the engagement recess 9, and the plate spring section 13 is hardly damaged.

Finally, to maintain the positioned state, the semiconductor laser 2 and the positioning member 4 are fixed to the holder 3 with the fixing member 5 as described below.

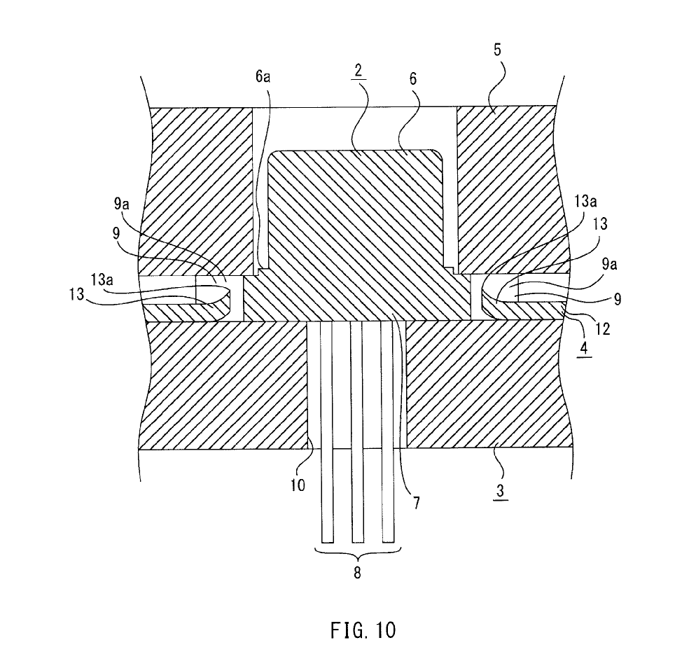

The side walls 17 of the fixing member 5 are mounted on the outer periphery of the base section 12 of the positioning member 4 (see FIG. 10). At this time, the light emission section 6 of the semiconductor laser 2 is inserted into the laser fixing hole 18 formed in the laser arrangement section 16. The flange 7 of the semiconductor laser 2 is pressed from above by the laser arrangement section 16 of the fixing member 5 to be pressed against the holder 3.

In this way, when the bottom surface of the flange 7 of the semiconductor laser 2 is pressed against the top surface of the holder 3, high contactness between the flange 7 and the holder 3 is ensured, and heat generated from the semiconductor laser 2 is sufficiently transferred to the holder 3. Therefore, high dissipation performance of the heat generated from the semiconductor laser 2 is achievable. Moreover, since high heat dissipation performance is ensured, the semiconductor laser 2 is applicable to high output use.

Subsequently, installation screws (not illustrated) are respectively inserted in order into the screw insertion holes 19 formed in the fixing member 5 and the screw insertion holes 15 formed in the positioning member 4, and the installation screws are respectively screwed to the screw holes 11 formed in the holder 3. As a result, the semiconductor laser 2 is fixed in a state of being positioned to the holder 3, and the optical unit 1 is accordingly configured (see FIG. 1).

### (Modifications of Positioning Member)

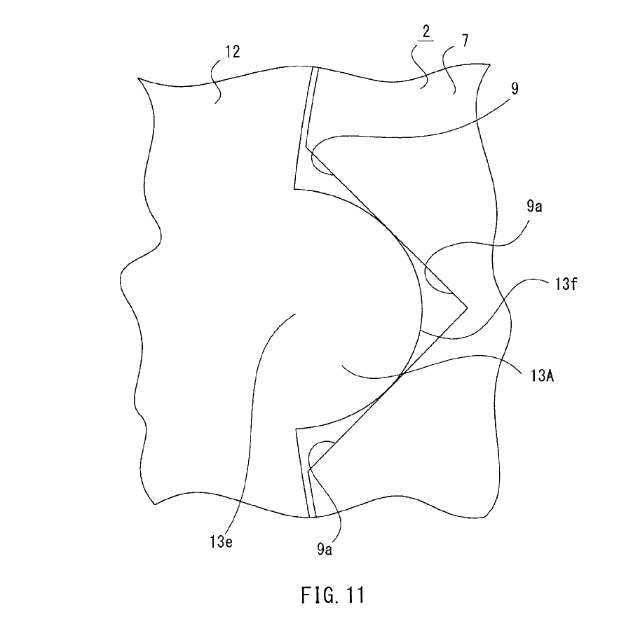

Modifications of the plate spring section will be described below (see FIG. 11 to FIG. 14).

### <First Modification>

A first modification is described first (see FIG. 11).

A plate spring section 13A according to the first modification is formed in a substantially semicircular shape in which the width thereof is gradually decreased from a base end 13e toward the front end. The outer periphery of the plate spring section 13A is formed as a curved surface 13f.

The plate spring section 13A is engaged with the engagement surfaces 9a of the semiconductor laser 2 in a state where two points of the curved surface 13f are elastically deformed by the engagement surfaces 9a.

Since the two points of the curved surface 13f of the plate spring section 13A are engaged with the engagement surfaces 9a of the semiconductor laser 2, the plate spring section 13A is hardly damaged, and abrasion of the plate spring section 13A is also allowed to be suppressed.

Moreover, since the plate spring section 13A is formed so that the base end 13e is the largest in width, strength of the base end 13e is high, and damage and unnecessary deformation of the plate spring section 13A are allowed to be suppressed accordingly.

### <Second Modification>

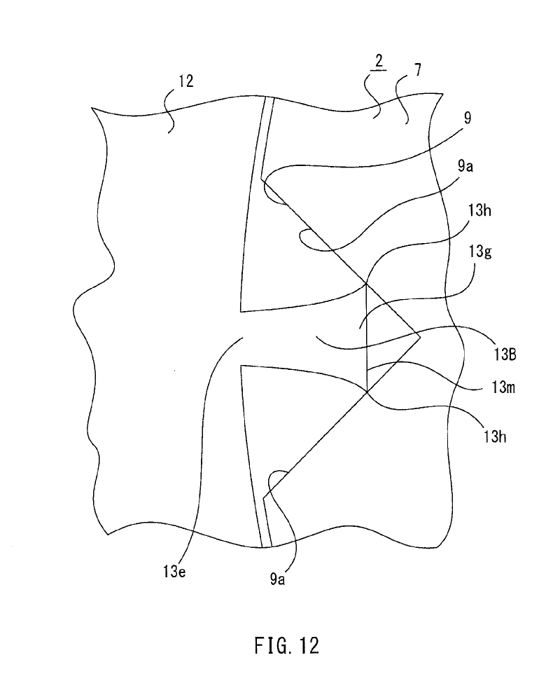

Next, a second modification is described (see FIG. 12).

A plate spring section 13B according to the second modification is formed so that the width thereof is gradually increased from the base end 13e toward the front end. In the plate spring section 13B, the base end 13e is the smallest in width, and a front end 13g is the largest in width. Both ends of the front end 13g in the width direction are formed as acute-angle parts 13h.

The plate spring section 13B is engaged with the engagement surfaces 9a of the semiconductor laser 2 in a state where the acute-angle parts 13h are elastically deformed by the engagement surfaces 9a.

Since the plate spring section 13B is formed so that the base end 13e is the smallest in width, the plate spring section 13B is easily elastically deformed, and thus it is possible to suppress load to the semiconductor laser 2 while securing high positioning accuracy of the semiconductor laser 2.

### <Third Modification>

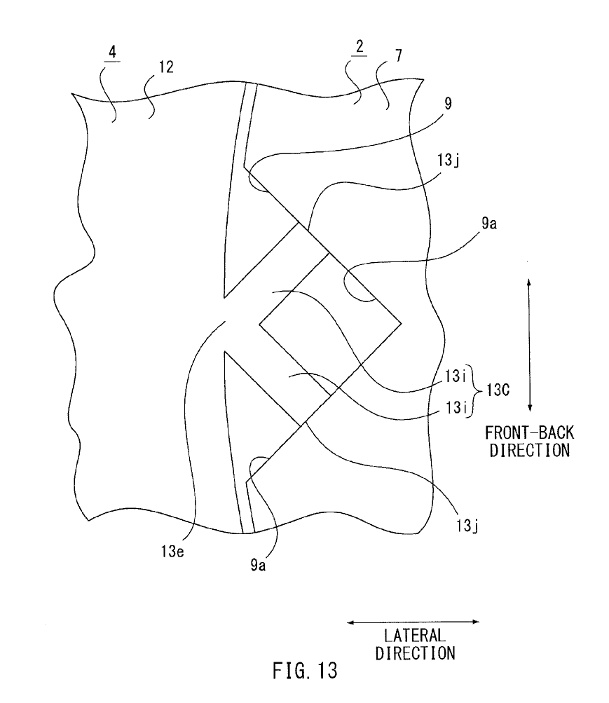

Next, a third modification is described (see FIG. 13).

A plate spring section 13C according to the third modification has two rectangular projections 13i that project from the base end 13e in a direction inclined by about 45 degrees with respect to the center direction of the through hole 14, and an angle between the projections 13i is about 90 degrees. The front end of each of the projections 13i is formed as a linear front edge 13j.

The plate spring section 13C is engaged with the engagement surfaces 9a of the semiconductor laser 2 in a state where the front edges 13j of the projections 13i are elastically deformed by the engagement surfaces 9a.

Since the front edges 13j of the two projections 13i of the plate spring section 13C are engaged with the engagement surfaces 9a of the semiconductor laser 2, it is possible to suppress influence of elastic deformation of one of the projections 13i on the other projection 13i.

Moreover, in the plate spring section 13C, the two projections 13i project by about 45 degrees with respect to the center direction of the through hole 14, and are engaged with the engagement surfaces 9a in a direction orthogonal thereto. Therefore, uniform force is applied to the engagement surfaces 9a both in the front-back direction and the lateral direction, and thus it is possible to perform positioning with high accuracy both in the front-back direction and the lateral direction.

### <Fourth Modification>

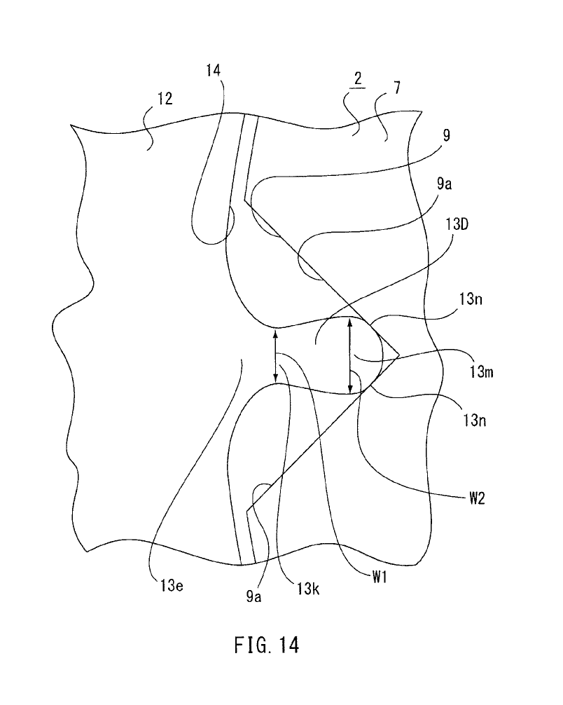

Finally, a fourth modification is described (see FIG. 14).

A plate spring section 13D according to the fourth modification has a shape in which the width thereof is once gradually decreased from the base end 13e toward the front end, then is gradually increased further toward the front end, and is gradually decreased again still further toward the front end. The part where the width is once narrowed is provided as a constriction part 13k, and the part where the width is the largest is provided as a wide part 13m. The plate spring section 13D is formed so that the width W1 of the constriction part 13k is smaller than the width W2 of the wide part 13m. Edges on both sides in the width direction of a part closer to the front end than the wide part 13m are formed as curved surfaces 13n.

The plat spring section 13D is engaged with the engagement surfaces 9a in a state where the curved surfaces 13n are elastically deformed by the engagement surfaces 9a.

Since the curved surfaces 13n of the plate spring section 13D are engaged with the engagement surfaces 9a of the semiconductor laser 2, the plate spring section 13D is hardly damaged, and abrasion thereof is also allowed to be suppressed.

### <Other Modifications>

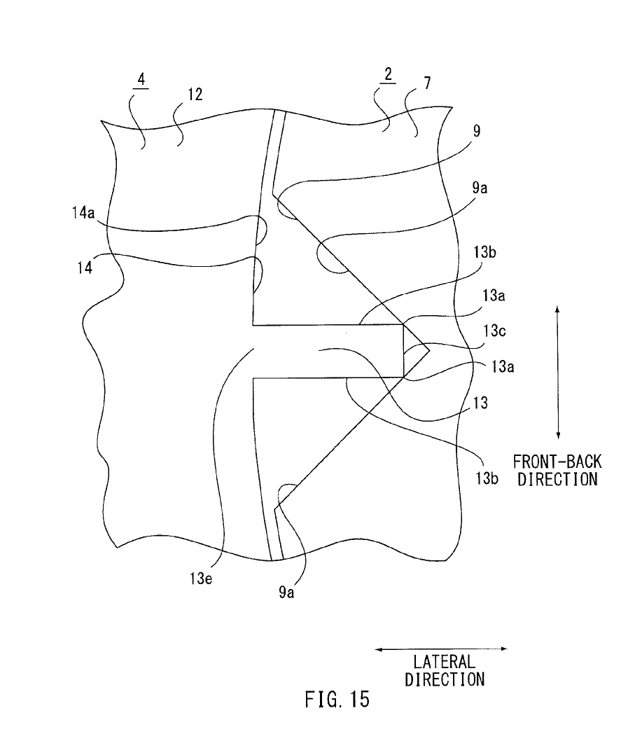

The example of the plate spring section 13 in which the side edges 13b and the opening edge 14a of the through hole 14 are connected by the curved continuous surfaces 13d is described above (see FIG. 4). Alternatively, as illustrated in FIG. 15, the side edges 13b of the plate spring section 13 and the opening edge 14a of the through hole 14 may intersect at an acute angle in the connection part.

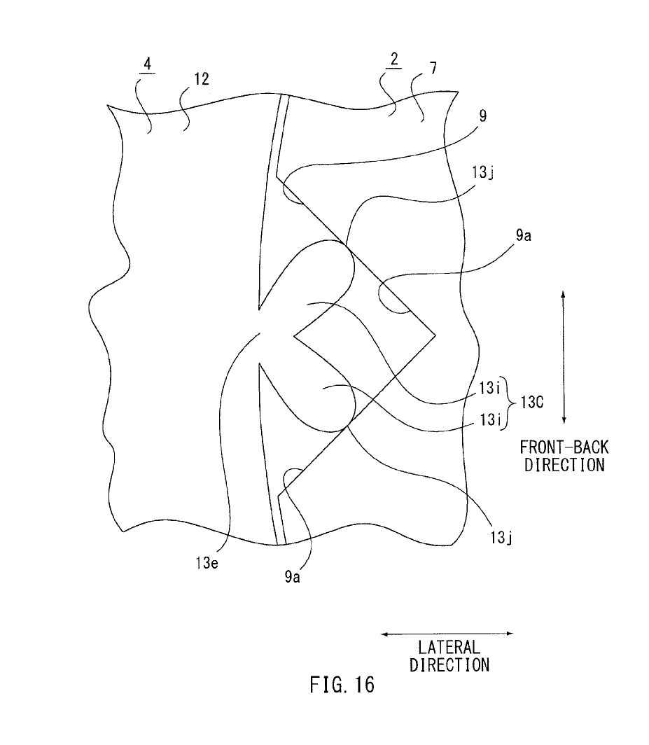

In addition, the example of the plate spring section 13C configured of the two rectangular projections 13i is described above (see FIG. 13). Alternatively, as illustrated in FIG. 16, the periphery of each of the two projections 13i of the plate spring section 13C may be formed with a curved surface.

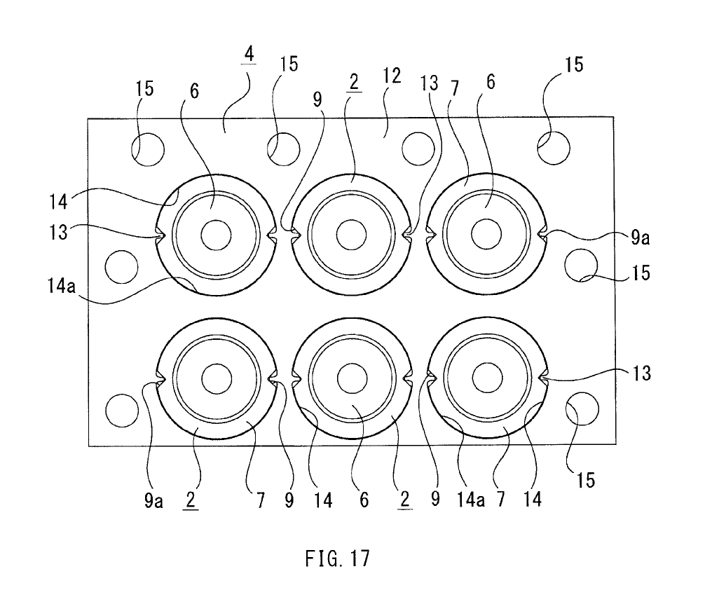

Further, in the above-described embodiment, the example in which the semiconductor lasers 2 are arranged in one line is described (see FIG. 2). Alternatively, as illustrated in FIG. 17, the semiconductor lasers 2 may be arranged in two or more lines.

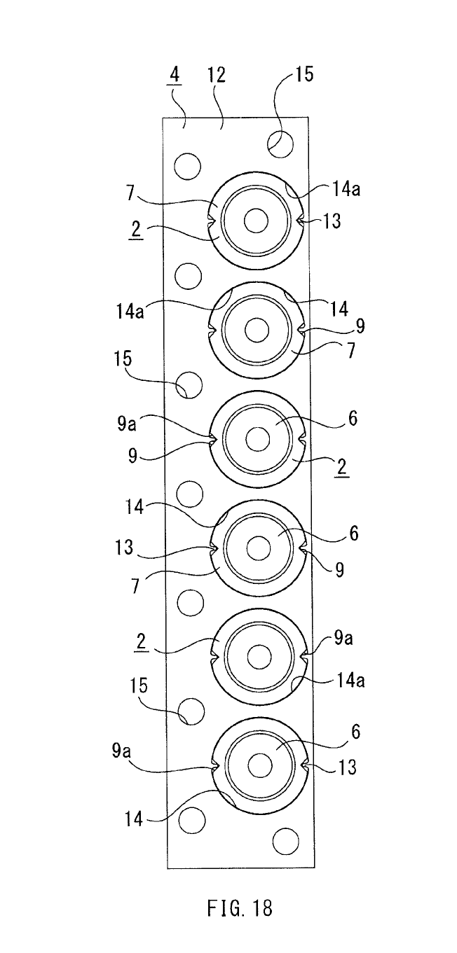

Furthermore, as illustrated in FIG. 18, the semiconductor lasers 2 may be arranged while being rotated by 90 degrees so that the plate spring sections 13 of each of the semiconductor lasers 2 are lined in a short direction of the positioning member 4.

An appropriate modification of the arrangement as described above allows the semiconductor lasers 2 to be used according to applications.

In addition, the width W1 of the constriction part 13k of the plate spring section 13D is smaller than the width W2 of the wide part 13m that is located on a side closer to the front end than the constriction part 13k. Therefore, the plate spring section 13D is easily elastically deformed, and it is possible to suppress load to the semiconductor laser 2 while securing high positioning accuracy of the semiconductor laser 2.

### CONCLUSION

As described above, the positioning member 4 has the base section 12 provided with the through hole 14 into which the semiconductor laser 2 is to be inserted, and the pair of plate spring sections 13 that is provided in the opening edge 14a of the through hole 14 so as to be opposed to each other by 180 degrees with the center of the through hole 14 in between and projects toward the mutually approaching direction. In addition, the plate spring sections 13 are engaged with the pair of engagement recesses 9 of the semiconductor laser 2 when the semiconductor laser 2 is inserted into the through hole 14, and are elastically deformable in the optical axis direction of the semiconductor laser 2.

Therefore, displacement in the straight line direction on the plane perpendicular to the optical axis and displacement in the rotation direction around the optical axis are suppressed. Consequently, it is possible to improve positioning accuracy of the semiconductor laser with respect to the holder.

It is to be noted that the present technology may be configured as follows.

(1) A semiconductor laser positioning member including:
a base section having a through hole into which a semiconductor laser is to be inserted, the semiconductor laser being configured to be disposed in a terminal insertion hole and having a pair of engagement recesses, the terminal insertion hole being formed in a holder; and
a pair of plate spring sections projecting from an opening edge of the through hole toward a mutually approaching direction, the pair of plate spring sections being opposed to each other by substantially 180 degrees with a center of the through hole in between, wherein
the plate spring sections are each formed in a symmetrical shape in a circumferential direction of the through hole,
the base section is overlapped with the holder when the semiconductor laser is inserted into the through hole, and
the plate spring sections are engaged with the respective engagement recesses, and are each elastically deformable in an optical axis direction of the semiconductor laser when the semiconductor laser is inserted into the through hole.

(2) The semiconductor laser positioning member according to (1), wherein
each of the engagement recesses has two engagement surfaces, and
the plate spring section is engaged with the two engagement surfaces at positions separated from each other in a direction substantially perpendicular to the optical axis direction.

(3) The semiconductor laser positioning member according to (1) or (2), wherein
each of the plate spring sections has corners, and
the corners are in contact with the corresponding engagement surfaces.

(4) The semiconductor laser positioning member according to (1) or (2), wherein
a part or all of a peripheral surface of each of the plate spring sections has a curved surface, and
the curved surface is in contact with the engagement surfaces.

(5) The semiconductor laser positioning member according to any one of (1) to (4), wherein a part where an outer periphery of the plate spring section and the opening edge of the through hole are continued has a curved surface.

(6) The semiconductor laser positioning member according to any one of (1) to (5), wherein the plate spring section includes a base end and a wide part, the base end being connected to the base section and having a width that is smaller than a width of the wide part being the largest in width.

(7) The semiconductor laser positioning member according to any one of (1) to (5), wherein the plate spring section includes a base end, the base end being connected to the base section and being the largest in width.

(8) The semiconductor laser positioning member according to any one of (1) to (7), wherein
each of the plate spring sections is configured of two projections, and
the projections are respectively engaged with the respective two engagement surfaces.

(9) The semiconductor laser positioning member according to any one of (1) to (3), wherein the plate spring section has a rectangular shape.

(10) An optical unit including:
a holder having a terminal insertion hole into which a semiconductor laser is configured to be arranged, the semiconductor laser having a pair of engagement recesses;
a positioning member having a base section and a pair of plate spring sections, the base section having a through hole into which the semiconductor laser is configured to be inserted, the pair of plate spring sections projecting from an opening edge of the through hole toward a mutually approaching direction, and being opposed to each other by substantially 180 degrees with a center of the through hole in between; and
a fixing member fixing the positioning member and the semiconductor laser to the holder, wherein
the plate spring sections are each formed in a symmetrical shape in a circumferential direction of the through hole,
the base section is overlapped with the holder when the semiconductor laser is inserted into the through hole, and
the plate spring sections are each engaged with the respective engagement recesses, and are each elastically deformable in an optical axis direction of the semiconductor laser when the semiconductor laser is inserted into the through hole.

Specific shapes and configurations of the respective sections described in the above-described embodiment of the disclosure are merely examples according to some embodiments of the present disclosure, and the technical scope of the present disclosure should not be construed restrictively by these examples.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor laser positioning member comprising:
a base section having a through hole into which a semiconductor laser is to be inserted, the semiconductor laser being configured to be disposed in a terminal insertion hole and having a pair of engagement recesses, the terminal insertion hole being formed in a holder; and
a pair of plate spring sections projecting from an opening edge of the through hole toward a mutually approaching direction, the pair of plate spring sections being opposed to each other by substantially 180 degrees with a center of the through hole in between, wherein
the plate spring sections are each formed in a symmetrical shape in a circumferential direction of the through hole,
the base section is overlapped with the holder when the semiconductor laser is inserted into the through hole, and
the plate spring sections are engaged with the respective engagement recesses, and are each elastically deformable in an optical axis direction of the semiconductor laser when the semiconductor laser is inserted into the through hole.

2. The semiconductor laser positioning member according to claim 1, wherein
each of the engagement recesses has two engagement surfaces, and
the plate spring section is engaged with the two engagement surfaces at positions separated from each other in a direction substantially perpendicular to the optical axis direction.

3. The semiconductor laser positioning member according to claim 1, wherein
each of the plate spring sections has corners, and
the corners are in contact with the corresponding engagement surfaces.

4. The semiconductor laser positioning member according to claim 1, wherein
a part or all of a peripheral surface of each of the plate spring sections has a curved surface, and
the curved surface is in contact with the engagement surfaces.

5. The semiconductor laser positioning member according to claim 1, wherein a part where an outer periphery of the plate spring section and the opening edge of the through hole are continued has a curved surface.

6. The semiconductor laser positioning member according to claim 1, wherein the plate spring section includes a base end and a wide part, the base end being connected to the base section and having a width that is smaller than a width of the wide part being the largest in width.

7. The semiconductor laser positioning member according to claim 1, wherein the plate spring section includes a base end, the base end being connected to the base section and being the largest in width.

8. The semiconductor laser positioning member according to claim 2, wherein
each of the plate spring sections is configured of two projections, and
the projections are respectively engaged with the respective two engagement surfaces.

9. The semiconductor laser positioning member according to claim 1, wherein the plate spring section has a rectangular shape.

10. An optical unit comprising:
a holder having a terminal insertion hole into which a semiconductor laser is configured to be arranged, the semiconductor laser having a pair of engagement recesses;
a positioning member having a base section and a pair of plate spring sections, the base section having a through hole into which the semiconductor laser is configured to be inserted, the pair of plate spring sections projecting from an opening edge of the through hole toward a mutually approaching direction, and being opposed to each other by substantially 180 degrees with a center of the through hole in between; and
a fixing member fixing the positioning member and the semiconductor laser to the holder, wherein
the plate spring sections are each formed in a symmetrical shape in a circumferential direction of the through hole,
the base section is overlapped with the holder when the semiconductor laser is inserted into the through hole, and
the plate spring sections are each engaged with the respective engagement recesses, and are each elastically deformable in an optical axis direction of the semiconductor laser when the semiconductor laser is inserted into the through hole.
